(19) United States
(12) Patent Application Publication
(10) Pub. No.: US 2015/0096797 A1
(43) Pub. Date: Apr. 9, 2015

(54) PACKAGE BOARD AND METHOD OF MANUFACTURING THE SAME

(71) Applicant: SAMSUNG ELECTRO-MECHANICS CO., LTD., Suwon-Si (KR)

(72) Inventor: Heung Ku Kim, Suwon-Si (KR)

(73) Assignee: SAMSUNG ELECTRO-MECHANICS CO., LTD., Suwon-Si (KR)

(21) Appl. No.: 14/247,552

(22) Filed: Apr. 8, 2014

(30) Foreign Application Priority Data
Oct. 7, 2013 (KR) 10-2013-0119238

(51) Int. Cl. H05K 3/38; H05K 3/06; H05K 3/10; H05K 1/09

(52) U.S. Cl. CPC H05K 3/384; H05K 1/09; H05K 3/06; H05K 3/10
USPC 174/261; 29/846

(57) ABSTRACT

Disclosed herein are a package board and a method of manufacturing the same. The package board includes: an insulating layer; and a ground layer formed in the insulating layer, wherein one side of the ground layer is formed so that a plurality of pattern parts having a plurality of diameters are spaced apart from each other and the other side thereof is continuously formed.

### CROSS REFERENCE TO RELATED APPLICATION

This application claims the benefit of Korean Patent Application No. 10-2013-0119238, filed on Oct. 7, 2013, entitled “Package board and Method of Manufacturing the Same”, which is hereby incorporated by reference in its entirety into this application.

### BACKGROUND OF THE INVENTION

1. Technical Field

The present invention relates to a package board and a method of manufacturing the same.

2. Description of the Related Art

In accordance with the rapid development of a semiconductor technology, a semiconductor device has significantly grown. Further, the development for a semiconductor package such as a system in package (SIP), a chip sized package (CSP), a flip chip package (FCP), or the like, configured as a package by mounting an electronic device such as the semiconductor device on a printed circuit substrate in advance has been actively conducted.

In order to implement high densification and high performance of the semiconductor package, the printed circuit board, which is a package board, includes a plurality of layers. In addition, the package board includes a ground layer to stably transfer an electrical signal (U.S. patent Ser. No. 06/790,760).

### SUMMARY OF THE INVENTION

The present invention has been made in an effort to provide a package board capable of preventing delamination by increasing an adhesive area and a method of manufacturing the same.

The present invention has been made in an effort to provide a package board capable of simultaneously preventing delamination and maintaining a transfer rate of an electrical signal and a method of manufacturing the same.

According to a preferred embodiment of the present invention, there is provided a package board, including: an insulating layer; and a ground layer formed in the insulating layer, wherein one side of the ground layer is formed so that a plurality of pattern parts having a plurality of diameters are spaced apart from each other and the other side thereof is continuously formed.

The pattern part of the ground layer may be formed so as to have an upper portion having a diameter larger than that of a lower portion.

The ground layer may have a side surface formed in a concave and convex shape.

The ground layer may further include a concave and convex having a surface roughness.

According to a preferred embodiment of the present invention, there is provided a method of manufacturing a package board, the method including: forming a first metal layer on a first insulating layer; forming a plurality of second metal layers formed so as to be spaced apart from each other on the first metal layer; forming an etching protection film on one surface and a side surface of the second metal layer; forming a ground layer including a pattern part having a plurality of diameters by etching the first metal layer; removing the etching protection film; and forming a second insulating layer on the ground layer.

The forming of the second metal layers may include: forming a first resist including a first opening part on the first metal layer; forming the second metal layer by plating the first opening part of the first resist; etching a side surface and an upper surface of the second metal layer; and after the forming of the etching protection film, removing the first resist.

The forming of the second metal layers may include: forming a first resist including a first opening part on the first metal layer; forming the second metal layer by plating the first opening part of the first resist; forming a second resist including a second opening part having a diameter larger than that of the first resist; etching the second metal layer exposed by the second opening part of the second resist; and after the forming of the etching protection film, removing the first resist.

In the forming of the etching protection film, the etching protection film may be formed by plating with nickel.

In the forming of the ground layer, the pattern part of the ground layer may be formed so as to have an upper portion having a diameter larger than that of a lower portion.

In the forming of the ground layer, the ground layer may have a side surface formed in a concave and convex shape.

In the forming of the ground layer, the first metal layer may be etched so as to have a depth smaller than a thickness of the first metal layer.

The first metal layer and the second metal layer may be made of the same metal.

The method may further include, after the forming of the etching protection film, performing a surface roughness process of the ground layer.

In the forming of the ground layer, the first metal layer may be isotropically etched.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a view showing a package board according to a preferred embodiment of the present invention;

FIGS. 2 to 13 are views showing a method of manufacturing a package board according to a preferred embodiment of the present invention; and

FIG. 14 is a view showing a package board according to another preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, a preferred embodiment of the present invention will be described in detail with reference to the accompanying drawings.

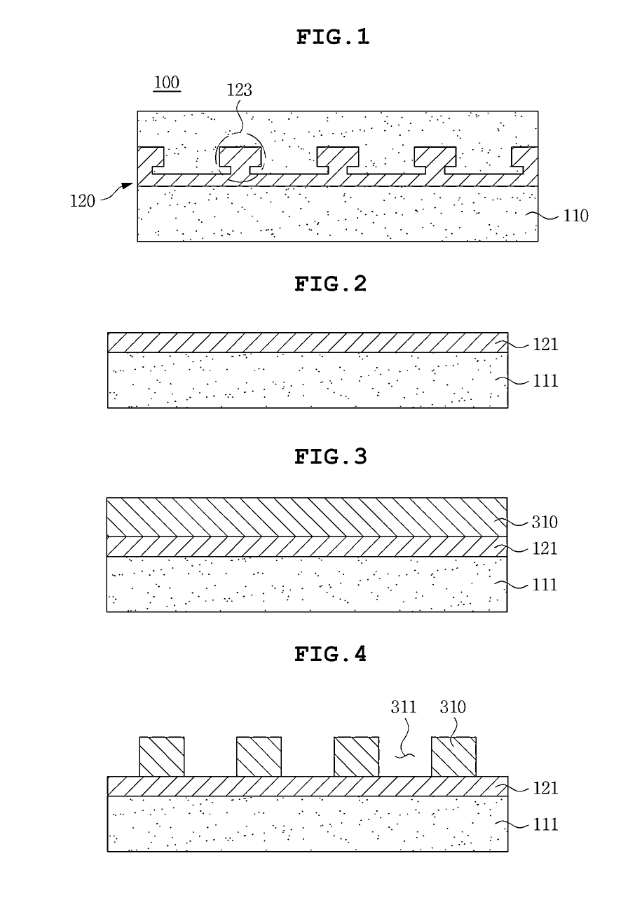

FIG. 1 is a view showing a package board according to a preferred embodiment of the present invention.

Referring to FIG. 1, a package board 100 may include an insulating layer 110 and a ground layer 120.

The insulating layer 110 may be made of a thermosetting resin such as an epoxy resin or a thermo-plastic resin such as polyimide. Alternatively, the insulating layer 110 may be made of a resin having a reinforcing material such as a glass fiber or an inorganic filler impregnated in the epoxy resin. For example, the insulating layer 110 may be made of prepreg. Alternatively, the insulating layer 110 may be made of a photocurable resin, or the like. However, the material of the insulating layer 110 is not particularly limited thereto.

The ground layer 120 may be formed in the insulating layer 110. The ground layer 120 may be made of a conductive metal. For example, the ground layer 120 may be made of copper. However, the material of the ground layer 120 is not limited to copper. That is, any conductive material which is used as the ground layer in a field of a circuit board may be used for the ground layer 120. The ground layer 120 may have a plurality of pattern parts 123 formed at one side thereof. The pattern part 123 may be formed to have a plurality of diameters. According to the preferred embodiment of the present invention, the pattern part 123 may be formed to have an upper portion having a diameter larger than that of a lower portion. In addition, the plurality of pattern part 123 may be spaced apart from each other by a predetermined distance.

The ground layer 120 formed by the structure as described above may have an increased adhesive area with the insulating layer 110. Therefore, the package board 100 according to the preferred embodiment of the present invention may improve adhesion between the ground layer 120 and the insulating layer 110. In addition, according to the preferred embodiment of the present invention, the insulating layer 110 fills concave portions of the pattern part 123 of the ground layer 120, thereby making it possible to prevent the insulating layer 110 from being delaminated. In addition, according to the preferred embodiment of the present invention, only one side of the ground layer 120 may be patterned and the other side thereof may be continuously formed as shown in FIG. 1. According to the prior art, in the case in which a through-hole is formed to increase an adhesive area, a transfer rate of an electrical signal is decreased at one side or the other side of the through-hole. However, the package board 100 according to the preferred embodiment of the present invention may constantly maintain the transfer rate of the electrical signal by continuously forming the ground layer 120.

In addition, according to the preferred embodiment of the present invention, although not shown in FIG. 1, the ground layer 120 may further include a concave and convex having a surface roughness. As the concave and convex having the surface roughness is formed on the ground layer 120, adhesion with the insulating layer 110 may be further improved.

In addition, although the preferred embodiment of the present invention shows a case in which the pattern part 123 of the ground layer 120 has a structure in which both sides thereof are symmetrical with each other, the present invention is not limited thereto. The pattern part 123 of the ground layer 120 may be patterned in any structure for increasing the adhesive area and preventing delamination.

Although the preferred embodiment of the present invention shows the case in which the package board 100 includes the insulating layer 110 and the ground layer 120, the present invention is not limited thereto. The package board 100 may include the insulating layer 110 and the ground layer 120 as well as a circuit pattern (not shown) for transferring the electrical signal which is formed on at least one of inside, one side, and the other side of the insulating layer 110.

FIGS. 2 to 13 are views showing a method of manufacturing a package board according to a preferred embodiment of the present invention.

Referring to FIG. 2, a first metal layer 121 may be formed on a first insulating layer 111.

The first insulating layer 111 may be made of a thermosetting resin such as an epoxy resin or a thermo-plastic resin such as polyimide. Alternatively, the first insulating layer 111 may be made of a resin having a reinforcing material such as a glass fiber or an inorganic filler impregnated in the epoxy resin. For example, the first insulating layer 111 may be made of prepreg. Alternatively, the first insulating layer 111 may be made of a photocurable resin, or the like. However, the material of the first insulating layer 111 is not particularly limited thereto.

The first metal layer 121 may be formed on one surface of the first insulating layer 111. The first metal layer 121 may be made of copper, for example. However, the material of the first metal layer 121 is not limited to copper. Any conductive material which is used as the ground layer in a field of a circuit board may be used as the material of the first metal layer 121. In addition, the first metal layer 121 may be formed by technologies known in the field of the circuit board such as an electroplating method, a lamination method, and the like.

Referring to FIG. 3, a first resist 310 may be formed.

The first resist 310 may be formed on one side of the first metal layer 121. According to a preferred embodiment of the present invention, the first resist 310 may be made of a photosensitive material. In addition, the first resist 310 may perform plating resist and etching resist functions. Here, the material of the first resist 310 is not limited to the photosensitive material. Any material may be used as the material of the first resist 310 as long as the first resist 310 may perform the plating resist and etching resist functions.

Referring to FIG. 4, a first opening part 311 may be formed in the first resist 310.

According to a preferred embodiment of the present invention, the first resist 310 may form the first opening part 311 by developing and exposing processes. A plurality of first opening parts 311 may be formed. The first opening part 311 of the first resist 310 may be formed so to expose a region in which the plating is performed on the first metal layer 121.

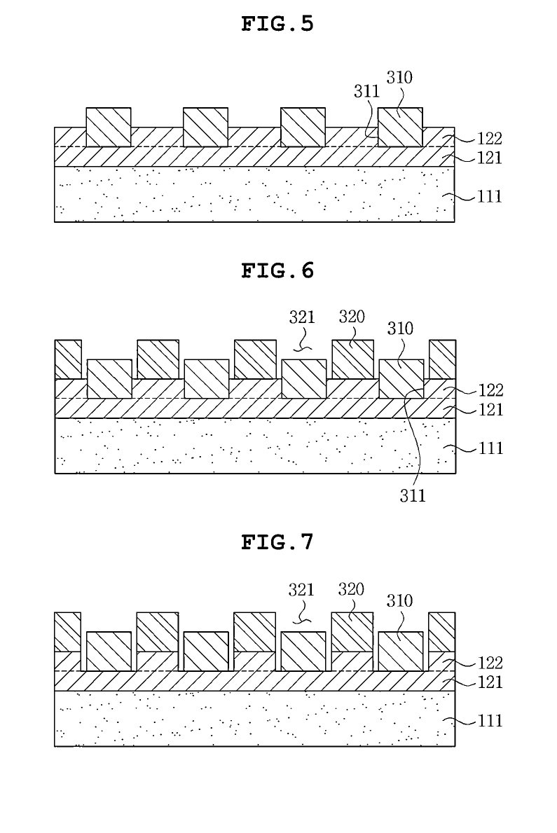

Referring to FIG. 5, a second metal layer 122 may be formed.

The second metal layer 122 may be formed in the first opening part 311 of the first resist 310. The second metal layer 122 may be made of copper, for example. However, the material of the second metal layer 122 is not limited to copper. Any conductive material which is used as the ground layer in a field of a circuit board may be used as the material of the second metal layer 122. According to a preferred embodiment of the present invention, the second metal layer 122 may be made of the same material as the first metal layer 121. The second metal layer 122 may be formed by technologies known in the field of the circuit board such as an electroplating method, and the like.

Referring to FIG. 6, a second resist 320 may be formed.

The second resist 320 may be formed on the second metal layer 122. In addition, the second resist 320 may include a second opening part 321. The second opening part 321 may be formed on the first resist 310 to expose the first resist 310. In addition, the second opening part 321 may have a diameter larger than that of the first resist 310. Therefore, the second resist 320 may be formed to expose the first resist 310 and a portion of the second metal layer 122 contacting both sides of the first resist 310.

The second resist 320 may be made of a photosensitive material. In addition, the second resist 320 may perform an etching resist function. Here, the material of the second resist 320 is not limited to the photosensitive material. Any material may be used as the material of the second resist 320 as long as the second resist 320 may perform the etching resist function.

According to a preferred embodiment of the present invention, in the case in which the second resist 320 is made of the photosensitive material, the second opening part 321 may be formed by developing and exposing processes.

Referring to FIG. 7, the second metal layer 122 may be etched.

A region exposed by the second opening part 321 of the second resist 320 may be etched. In this case, the first resist 310 is formed in the second opening part 321 of the second resist 320, such that the first metal layer 121 of a region on which the first resist 310 is formed may also be protected from the etching process. As a result, as shown in FIG. 7, only the second metal layer 122 exposed by the first resist 310 and the second resist 320 may be etched. Therefore, the second metal layer 122 may be formed so as to be spaced apart from a side surface of the first resist 310 by a predetermined distance.

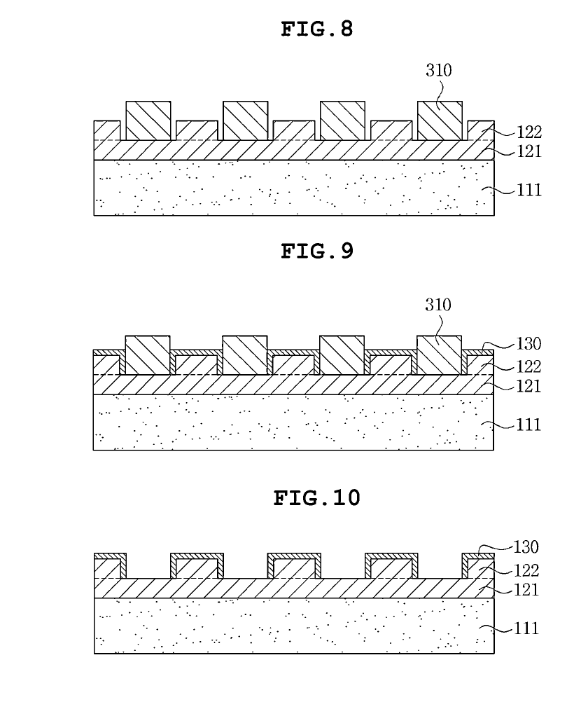

Referring to FIG. 8, the second resist (320 of FIG. 7) may be removed.

In order to form the second metal layer 122 which is formed so as to be spaced apart from the first resist 310 as shown in FIG. 8, a preferred embodiment of the present invention describes a case of using the second resist (320 of FIGS. 6 and 7) as an example. However, in order to form the second metal layer 122 shown in FIG. 8, the second resist (320 of FIGS. 6 and 7) is not necessarily used. An etchant used when etching the second metal layer 122 may permeate between the first resist 310 and the second metal layer 122. In the case in which the etchant permeates between the first resist 310 and the second metal layer 122, a side surface of the second metal layer 122 may be etched. Therefore, in the case in which the etching process is performed without forming the second resist (320 FIGS. 6 and 7), an upper surface and the side surface of the second metal layer 122 may be simultaneously etched. That it, according to a preferred embodiment of the present invention, even in the case in which the second metal layer 122 is etched in a state in which the processes of FIGS. 6 and 7 are omitted after the process of FIG. 5, the second metal layer 122 shown in FIG. 8 may be formed.

Referring to FIG. 9, an etching protection film 130 may be formed.

The etching protection film 130 may be formed on the second metal layer 122 exposed by the first resist 310. That is, the etching protection film 130 may be formed on one surface of the second metal layer 122. Alternatively, the etching protection film 130 may be formed on the side surface of the second metal layer 122. Here, the etching protection film 130 is formed between the second metal layer 122 and the first resist 310, such that it may be formed on the side surface of the second metal layer 122.

According to a preferred embodiment of the present invention, the etching protection film 130 may be made of nickel. However, a material of the etching protection film 130 is not limited to nickel. Any material may be used as long as the etching protection film 130 may protect the first metal layer 121 and the second metal layer 122 from the etching process. In addition, the etching protection film 130 may be formed by an electroplating method. A process of forming the etching protection film 130 is also not limited to the electroplating method. That is, any method may be used as long as the etching protection film having the same structure as the etching protection film 130 shown in FIG. 9 may be formed.

Referring to FIG. 10, the first resist (310 of FIG. 9) may be removed.

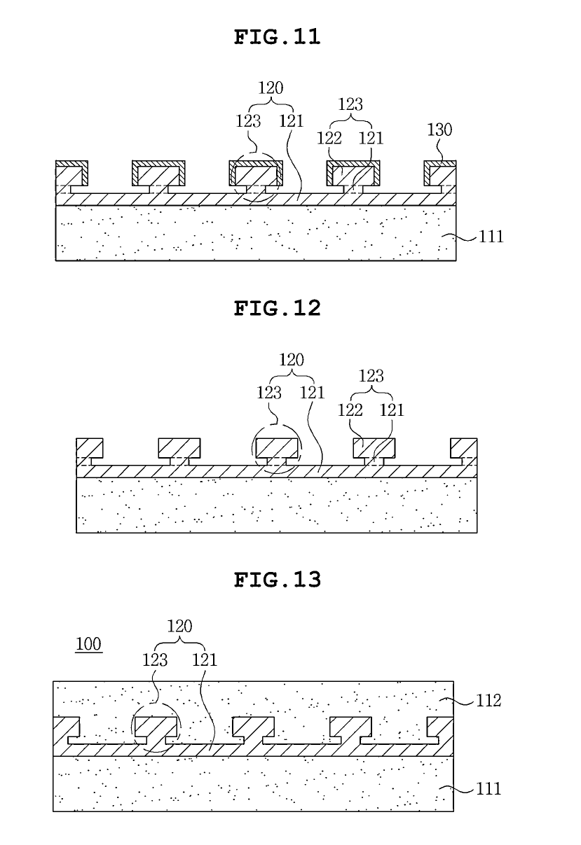

Referring to FIG. 11, the first metal layer 121 may be etched.

The first metal layer 121 exposed by removing the first resist (310 of FIG. 9) may be etched. In this case, the first metal layer 121 may be isotropically etched. That is, the first metal layer 121 may be removed from one side direction to the other side direction and may also be removed in both side directions. In this case, the second metal layer 122 may be protected from the etching process by the etching protection film 130.

By the etching process as described above, the ground layer 120 including the pattern part 123 having the plurality of diameters may be formed. According to the preferred embodiment of the present invention, the pattern part 123 may be formed to have an upper portion having a diameter larger than that of a lower portion. Here, the upper portion of the pattern part 123 may be the second metal layer 122 and the lower portion thereof may be the first metal layer 121 remaining after performing the etching. The first metal layer 121 is isotropically etched, such that the second metal layer 122 may have the diameter larger than that of the first metal layer 121. The pattern part 123 formed as described above increases an adhesive area with the insulating layer to be later formed, thereby making it possible to improve adhesion.

The ground layer 120 according to the preferred present embodiment may include the pattern part 123. In this case, the pattern part 123 may be formed on one side of the ground layer 120. The other side of the ground layer 120 may be the other side of the first metal layer 121 which is not etched. That is, the ground layer 120 according to the preferred embodiment of the present invention may have one side on which a plurality of pattern parts 123 are formed so as to be spaced apart from each other and the other side formed so as to have a continuous structure.

Referring to FIG. 12, the etching protection film (130 of FIG. 11) may be removed.

Referring to FIG. 13, a second insulating layer 112 may be formed.

The second insulating layer 112 is formed on the ground layer 120, thereby making it possible to bury the ground layer 120. The second insulating layer 112 may be made of a thermosetting resin such as an epoxy resin or a thermo-plastic resin such as polyimide. Alternatively, the second insulating layer 112 may be made of a resin having a reinforcing material such as a glass fiber or an inorganic filler impregnated in the epoxy resin. For example, the second insulating layer 112 may be made of prepreg. Alternatively, the second insulating layer 112 may be made of a photocurable resin, or the like. However, the material of the second insulating layer 112 is not particularly limited thereto. According to a preferred embodiment of the present invention, the second insulating layer 112 may be made of the same material as the first insulating layer 111.

According to a preferred embodiment of the present invention, an adhesive area between the ground layer 120 and the second insulating layer 112 is increased by the pattern part 123 of the ground layer 120, thereby making it possible to improve adhesion. In addition, according to a preferred embodiment of the present invention, the second insulating layer 112 may be filled in a lower portion of a concavely patterned pattern part 123 of the ground layer 120. By the structure of the ground layer 120 as described above, delamination of the second insulating layer 112 may be prevented. In addition, according to a preferred embodiment of the present invention, the other side of the ground layer 120 is continuously formed, such that a transfer rate of an electrical signal transferred from one side or the other side of the ground layer 120 may be constantly maintained.

According to another preferred embodiment of the present invention, a surface roughness process may be further performed on the ground layer 120 before forming the second insulating layer 112. In the case in which the surface roughness process is performed on the ground layer 120, adhesion between the ground layer 120 and the second insulating layer 112 may be further increased.

Although the preferred embodiment of the present invention shows a structure in which both sides of the pattern part 123 of the ground layer 120 are symmetrical with each other, the pattern part 123 may be patterned in any structure capable of increasing the adhesive area and preventing delamination.

Although the preferred embodiment of the present invention shows the case in which the package board 100 includes the first insulating layer 111, the second insulating layer 112, and the ground layer 120, as an example, the present invention is not limited thereto. The package board 100 may include a circuit pattern (not shown) for transferring the electrical signal which is formed on at least one of inside, one side, and the other side of the first insulating layer 111 and the second insulating layer 112.

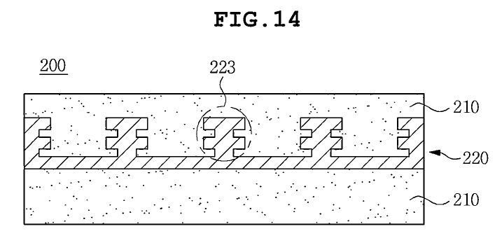

FIG. 14 is a view showing a package board according to another preferred embodiment of the present invention.

Referring to FIG. 14, a package board 200 may include an insulating layer 210 and a ground layer 220.

The insulating layer 210 may be made of a thermosetting resin such as an epoxy resin or a thermo-plastic resin such as polyimide. Alternatively, the insulating layer 210 may be made of a resin having a reinforcing material such as a glass fiber or an inorganic filler impregnated in the epoxy resin. For example, the insulating layer 210 may be made of prepreg. Alternatively, the insulating layer 210 may be made of a photocurable resin. However, the material of the insulating layer 210 is not particularly limited thereto.

The ground layer 220 may be formed in the insulating layer 210. The ground layer 220 may be made of a conductive metal. For example, the ground layer 220 may be made of copper. However, the material of the ground layer 220 is not limited to copper. That is, any conductive material which is used as the ground layer in a field of a circuit board may be used for the ground layer 220. The ground layer 220 may have a plurality of pattern parts 223 formed at one side thereof. The pattern part 223 may be formed to have a plurality of diameters. According to a preferred embodiment of the present invention, a side surface of the pattern part 223 may be formed in a concave and convex shape having two concave structures and two convex structures. The plurality of pattern parts 223 formed as described above may be spaced apart from each other by a predetermined distance.

The ground layer 220 according to a preferred embodiment of the present invention has an increased adhesive area with the insulating layer 210 by the structure of the pattern part 223, thereby making it possible to improve adhesion. In addition, according to the preferred embodiment of the present invention, the insulating layer 210 fills concave portions of the pattern part 223 of the ground layer 220, thereby making it possible to prevent the insulating layer 210 from being delaminated. In addition, according to the preferred embodiment of the present invention, only one side of the ground layer 220 may be patterned and the other side thereof may be formed so as to have a continuous structure. Therefore, the transfer rate of the electrical signal transferred from one side or the other side of the ground layer 220 may be constantly maintained.

In addition, according to the preferred embodiment of the present invention, although not shown in FIG. 14, the ground layer 220 may further include a concave and convex having a surface roughness. As the concave and convex having the surface roughness is formed on the ground layer 220, adhesion with the insulating layer 210 may be further improved.

According to the preferred embodiment of the present invention, although not shown, the package board 200 may include a circuit pattern (not shown) for transferring the electrical signal which is formed on at least one of inside, one side, and the other side of the insulating layer 210.

The package board and the method of manufacturing the same according to the preferred embodiment of the present invention may pattern the ground layer to thereby prevent delamination between the insulating layer and the ground layer.

The package board and the method of manufacturing the same according to the preferred embodiment of the present invention may simultaneously implement the prevention of delamination between the insulating layer and the ground layer and the maintenance of the transfer rate of the electrical signal.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A package board, comprising:
an insulating layer; and
a ground layer formed in the insulating layer,
wherein one side of the ground layer is formed so that a plurality of pattern parts having a plurality of diameters are spaced apart from each other and the other side thereof is continuously formed.

2. The package board as set forth in claim 1, wherein the pattern part of the ground layer is formed so as to have an upper portion having a diameter larger than that of a lower portion.

3. The package board as set forth in claim 1, wherein the ground layer has a side surface formed in a concave and convex shape.

4. The package board as set forth in claim 1, wherein the ground layer further includes a concave and convex having a surface roughness.

5. A method of manufacturing a package board, the method comprising:
forming a first metal layer on a first insulating layer;
forming a plurality of second metal layers formed so as to be spaced apart from each other on the first metal layer;
forming an etching protection film on one surface and a side surface of the second metal layer;
forming a ground layer including a pattern part having a plurality of diameters by etching the first metal layer;
removing the etching protection film; and
forming a second insulating layer on the ground layer.

6. The method as set forth in claim 5, wherein the forming of the second metal layers includes:
forming a first resist including a first opening part on the first metal layer;
forming the second metal layer by plating the first opening part of the first resist;
etching a side surface and an upper surface of the second metal layer; and
after the forming of the etching protection film, removing the first resist.

7. The method as set forth in claim 5, wherein the forming of the second metal layers includes:
forming a first resist including a first opening part on the first metal layer;
forming the second metal layer by plating the first opening part of the first resist;
forming a second resist including a second opening part having a diameter larger than that of the first resist;
etching the second metal layer exposed by the second opening part of the second resist; and
after the forming of the etching protection film, removing the first resist.

8. The method as set forth in claim 5, wherein in the forming of the etching protection film, the etching protection film is formed by plating with nickel.

9. The method as set forth in claim 5, wherein in the forming of the ground layer, the pattern part of the ground layer is formed so as to have an upper portion having a diameter larger than that of a lower portion.

10. The method as set forth in claim 5, wherein in the forming of the ground layer, the ground layer has a side surface formed in a concave and convex shape.

11. The method as set forth in claim 5, wherein in the forming of the ground layer, the first metal layer is etched so as to have a depth smaller than a thickness of the first metal layer.

12. The method as set forth in claim 5, wherein the first metal layer and the second metal layer are made of the same metal.

13. The method as set forth in claim 5, further comprising, after the forming of the etching protection film, performing a surface roughness process of the ground layer.

14. The method as set forth in claim 5, wherein in the forming of the ground layer, the first metal layer is isotropically etched.
